(19) United States
(12) Patent Application Publication
(10) Pub. No.: US 2026/0017431 A1
(43) Pub. Date: Jan. 15, 2026

(54) RESIDUAL PHYSICS SYSTEM

(71) Applicant: Sony Interactive Entertainment Europe Limited, London (GB)

(72) Inventors: Andrew James Bigos, London (GB); Roc Ramon Currius, London (GB); Daniel Montero Motilla, London (GB); Nabajeet Barman, London (GB); Matthew William Sanders, London (GB)

(21) Appl. No.: 19/267,365

(22) Filed: Jul. 11, 2025

(30) Foreign Application Priority Data
Jul. 12, 2024 (GB) 2410212.1

(51) Int. Cl. G06F 30/20

(52) U.S. Cl. CPC G06F 30/20

(57) ABSTRACT

A method of calculating a plurality of residuals and synchronising a first physics state with a second physics state by applying one of the residuals to the first physics state, at a first computing device, and a computer system for carrying out the method. The computer-implemented method includes the steps of, at a first computing device: receiving physics data; running a first simulation having a first attribute, using the physics data, to provide a first physics state; running a second simulation having a second attribute, using the physics data, to provide a second physics state; and calculating a plurality of residuals. Each residual is the difference between the first physics state and the second physics state at a selected time. The method further includes the step of, at the first computing device, synchronising the first physics state with the second physics state by applying one of the residuals to the first physics state.

### CROSS-REFERENCE TO RELATED APPLICATIONS

This application claims priority to UK Patent Application No. 2410212.1, filed on Jul. 12, 2024, the disclosures of which are incorporated by reference.

### FIELD

The present disclosure relates to a method of calculating a plurality of residuals and synchronising a first physics state with a second physics state by applying one of the residuals to the first physics state, at a first computing device, and a computer system for carrying out the method.

### BACKGROUND

A traditional games console, on which a video game may be played by one or more users, comprises a computer system connected to a display and one or more user input devices such as controllers. The computer system stores instructions to run the game, updating the game according to input received from the controllers and displaying the current game state on the display.

In recent years there has been a move towards cloud gaming, in which a user device is connected to a cloud gaming server over the Internet. The game is hosted on the server and frames of audio-visual data representing the current game state are sent to the user device for display. The user device registers user input and sends it to the server, which updates the game state.

A game engine running on the cloud gaming server handles all the computational heavy lifting, while the user device primarily functions as a display and input interface. A physics engine is a software component or module within a game engine that simulates physical interactions and behaviours in a virtual environment. It is generally difficult to improve physics simulations running on a physics engine because the effort needed to increase the quality of physics simulations can be unpredictable e.g., the most common way to improve the fidelity is to decrease the simulation step time, but this can become a burden on a local physics simulator and result in unpredictable computational loads.

An alternative would be to run the physics on a remote device with a larger compute capacity, but this suffers because it introduces a latency into the system that may not be acceptable; and the system may fail catastrophically if the physics data does not arrive to the local system in time.

For the best user experience when cloud gaming, low latency is required. Latency issues with physics engines in cloud gaming can arise due to the inherent challenges of transmitting data between the user device and the cloud server. Physics simulations require rapid and accurate communication between the user device and the server, and any delays in this communication can lead to noticeable latency or lag in the gameplay experience.

Network latency contributes to latency issues with physics engines in cloud gaming. When playing over a wired connection such as broadband, even if the end-point connection to the device is wireless, latency can be minimised. However, if the user device is connecting to the Internet via a wireless communication system such as mobile internet access (e.g. 4G, 5G), the connection may be slow.

Server processing time also contributes to latency issues. Physics simulations require computational resources to calculate and simulate object interactions. If the cloud server is under heavy load or has limited processing power, it may struggle to perform these calculations quickly, leading to delays in updating the game state.

While advancements in technology and infrastructure continue to improve the cloud gaming experience, minimising latency remains a significant challenge in delivering responsive and immersive gameplay, particularly for physics-intensive games.

### SUMMARY

Throughout this specification the word “comprise”, or variations such as “includes”, “comprises”, or “comprising”, will be understood to imply the inclusion of a stated element, integer, step, or group of elements, integers, or steps, but not the exclusion of any other element, integer, step, or group of elements, integers, or steps.

In a first aspect, the present disclosure provides a computer-implemented method according to claim 1.

In a second aspect, the present disclosure provides a computing device according to claim 14.

In a third aspect, the present disclosure provides a system according to claim 15.

In a fourth aspect, the present disclosure provides a computer-readable medium according to claim 19.

In a fifth aspect, the present disclosure provides instructions according to claim 20.

It will be appreciated that any features described herein as being suitable for incorporation into one or more aspects or embodiments of the present disclosure are intended to be generalisable across any and all aspects and embodiments of the present disclosure. Other aspects of the present disclosure can be understood by those skilled in the art in light of the description, the claims, and the drawings of the present disclosure. The foregoing general description and the following detailed description are exemplary and explanatory only and are not restrictive of the claims.

### BRIEF DESCRIPTION OF THE FIGURES

Embodiments of the present disclosure will now be described with reference to the accompanying drawings, where:

FIG. 1 shows an exemplary environment in which the disclosure may be carried out;

FIG. 2 is a simplified illustrative diagram of a datacentre shown in FIG. 1;

FIG. 3 is a simplified illustrative diagram of a cloud gaming server shown in FIG. 2;

FIG. 4 is a simplified illustrative diagram of the contents of a memory shown in FIG. 3;

FIG. 5 shows steps carried out at a game engine shown in FIG. 4;

FIG. 6 is a simplified illustrative diagram of a dedicated physics simulator;

FIG. 7 is an overview of communication between a game engine, local physics simulator, and dedicated physics simulator;

FIG. 8 shows steps to update a game state using user input;

FIG. 9 shows steps to run a third simulation at a local physics simulator;

FIG. 10 shows steps to run a first simulation and second simulation at a dedicated physics simulator;

FIG. 11 details steps for synchronising a mirrored state with an accelerated state, at the dedicated physics simulator shown in FIG. 6;

FIG. 12 details steps for synchronising a local state with an accelerated state, at a local physics simulator.

### DETAILED DESCRIPTION

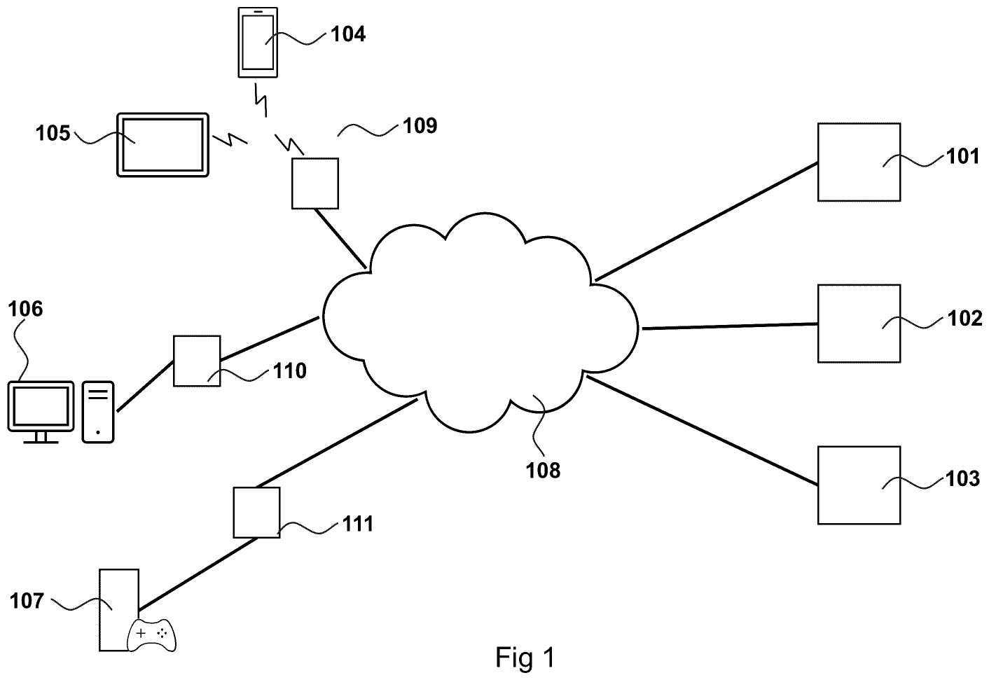

FIG. 1 shows an exemplary environment in which the disclosure herein described may be carried out. Datacentres, such as datacentres 101, 102 and 103, host cloud gameplay sessions with user devices, such as user devices 104, 105, 106 and 107. Communication between all the systems shown is via internet 108, although any other network may be used. Datacentres 101 to 103 are connected to internet 108 by high-speed wired connections. In the example of FIG. 1, user device 104 is a mobile telephone and user device 105 is a tablet, both of which connect to internet 108 using a SIM card or similar, via wireless connections to base station 109. User device 106 is a home computer system connected via a wired connection to a router 110 which has a wired connection to internet 108, and user device 107 is a games console connected via WiFi to a router 111 which has a wired connection to internet 108. Other types of user device and other connections to a network are envisaged.

Each of datacentres 101 to 103 typically comprises a number of servers, each of which hosts one or more cloud gameplay sessions with one or more user devices.

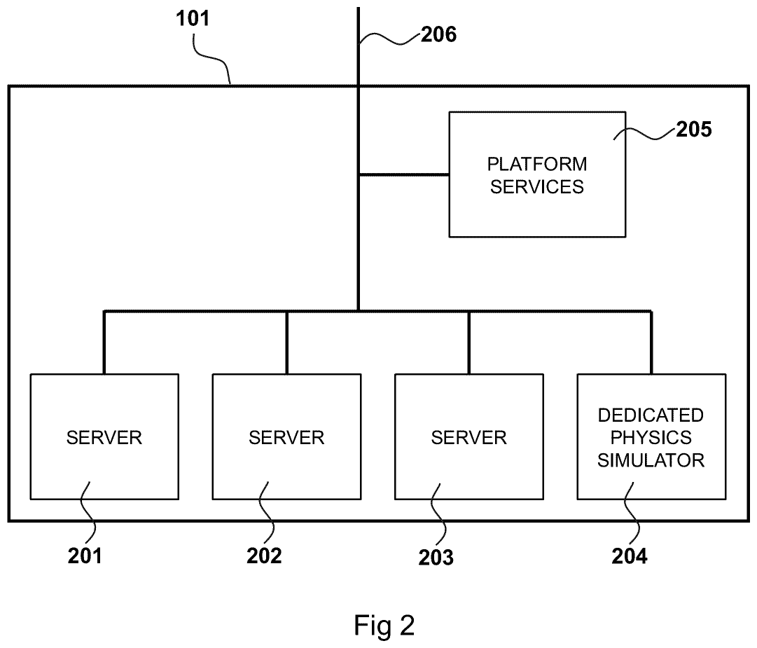

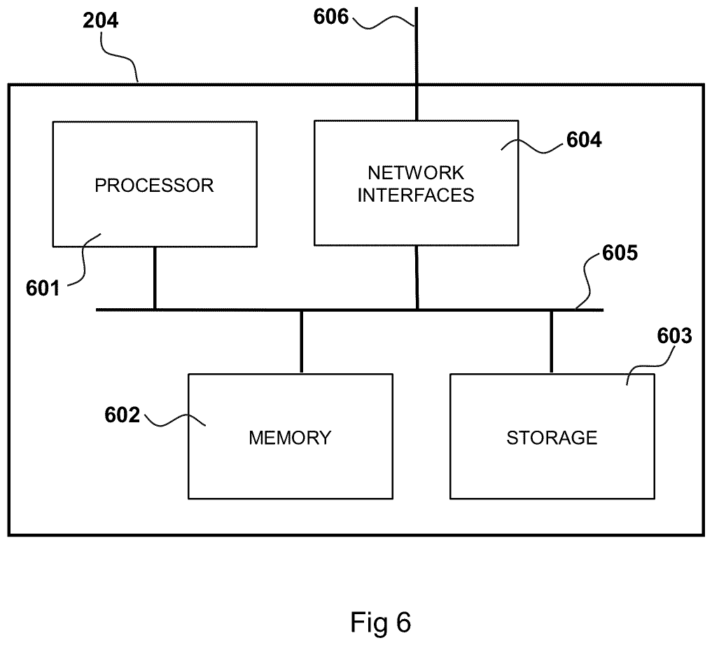

FIG. 2 is a simplified illustrative diagram of datacentre 101. Datacentres 102 and 103 are similar. It includes three cloud gaming servers 201, 202 and 203, a dedicated physics simulator 204, and a platform services system 205. A game engine runs on each of the three cloud gaming servers 201, 202 and 203. Connection to internet 108 is via connection 206. Each server hosts one or more sessions, each session pertaining to a game being played by one or more users; for example, server 201 hosts session 211. In an alternative implementation, the dedicated physics simulator 204 may not be provided in the datacentre 101 and may, instead, be provided as one or more nodes on a high-performance computing facility. The dedicated physics simulator 204 will be described further with reference to FIG. 6.

Platform services system 205 provides services such as user log-in, retrieving and changing user account details, accessing saved games, providing lobbies, load balancing, etc. User settings and saved games are stored in a networked location so that they are accessible to all datacentres; this may be in one of the datacentres, distributed across all the datacentres, or another location.

Platform services system 205 allocates new sessions to servers when requests for games are received from user devices, after which the servers communicate directly with the user devices. Platform services system 205 may be a single computer system, a set of computer systems each running different services, a set of virtual machines, or a distributed system.

Datacentres can be configured in many ways, and this configuration is only an example of a suitable datacentre. For example, rather than having a dedicated server for a game, a load balancing system may distribute the game across the servers. It will be understood that while the description herein focusses on dedicated servers, other architectures are within the scope of the claims. In addition, while the servers described herein are computer systems, they may be virtual machines.

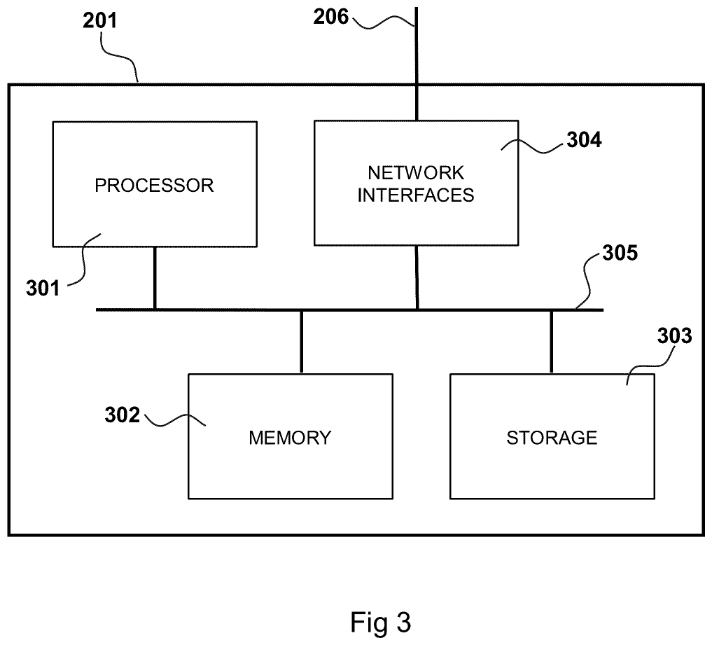

FIG. 3 is a simplified illustrative diagram of cloud gaming server 201. Servers 202 to 204, and servers in other datacentres, may be similar. It includes a processor 301, which may include one or more processing units such as CPU's, memory 302 such as RAM memory, and local storage 303 such as one or more disk drives. One or more network interfaces 304 provide an interface to connection 206, via which the server may be configured for first use, instructions may be loaded, and requests may be served. The components 301 to 304 are connected by a bus 305. The diagram shown in FIG. 3 is merely an example of a suitable server, and server 201 may be any kind of computer system including a virtual or distributed server.

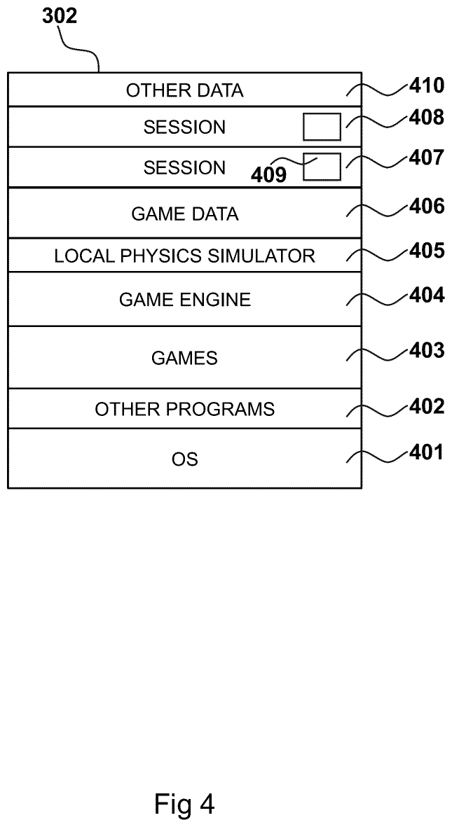

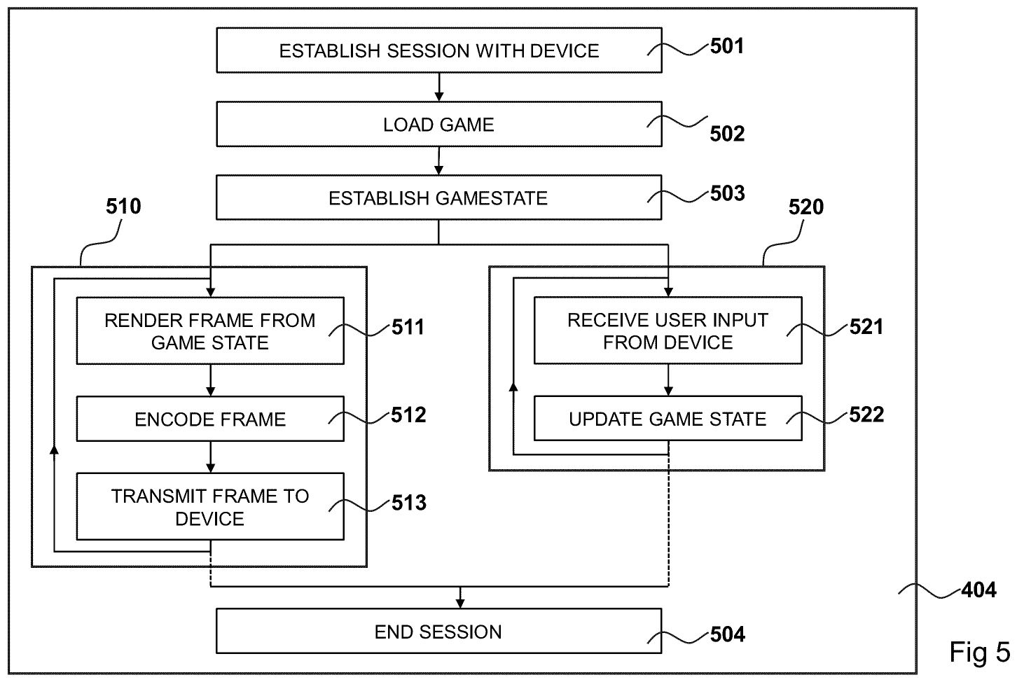

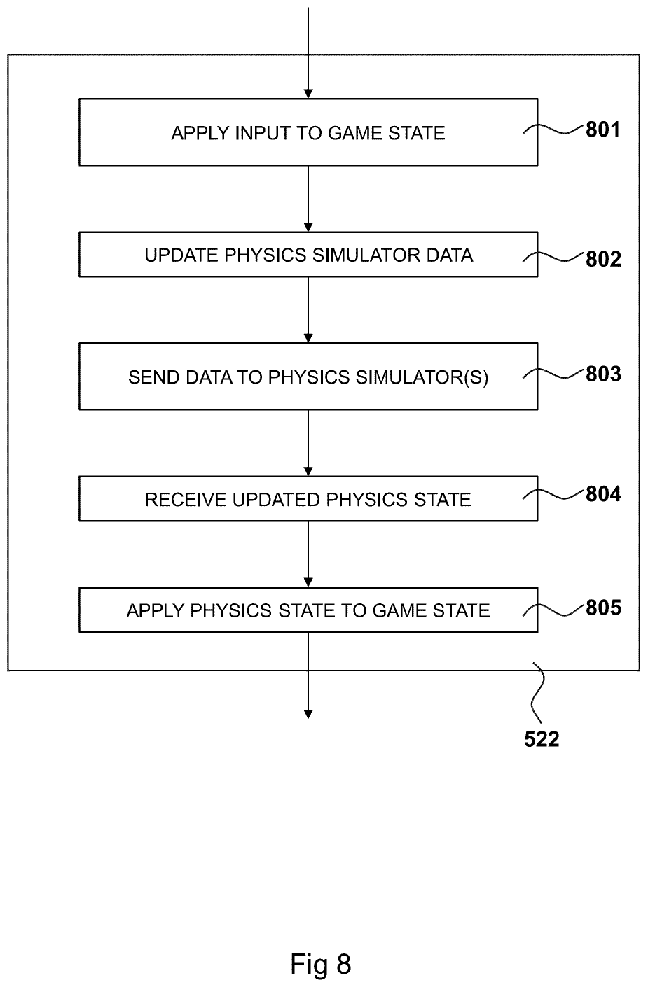

FIG. 4 is a simplified illustrative diagram of the contents of memory 302 while server 201 is running. Operating system 401 and other programs 402 necessary for the basic operation of server 201 are not described further herein. Games 403 comprises instructions for all the games being played in sessions on server 201. Game engine 404 is a software framework or platform, which typically includes features such as rendering graphics, managing audio, input devices, scripting, animation, artificial intelligence, and networking. Local physics simulator 405, which may be provided as a software component or module within game engine 404, simulates physical interactions and behaviours in a virtual environment. The local physics simulator 405 may be provided as an external third-party library (middleware for physics). The cloud games, provided to user devices, in Games 403 are loadable into the game engine 404. Game engine 404 will be described further with reference to FIGS. 5 and 8.

Data held on memory 302 includes generic game data 406 for each game being played, and data required by the game engine 404 includes one or more cloud gameplay sessions, such as sessions 407 and 408. Each session includes user details and settings and a game state for the game, for example session 407 includes game state 409. Each session also includes any other data required for the game to be played. Memory 302 finally comprises any other data 410 required by programs running on server 201.

The basic steps of the game engine 404, carried out by processor 301 when running a program, are shown in FIG. 5. Instructions for game engine 404 are copied to storage 303 from a networked location via network interface 305 or by any other suitable method, loaded into memory 302 from storage 303 when required, and carried out by processor 301. Game engine 404 may be any type of suitable software, and may be suitable for being carried out on a single CPU, a processor chip comprising multiple CPUs, a distributed processor either in a physical location or in a cloud computing environment, or any other suitable processor. Game engine 404 may be used to play multiple games, or may be instantiated such that there is an instance for each session.

Platform services system 205 receives a request from a user device, for example user device 104, for a cloud game to be played using the settings for a particular user, and allocates the request to server 201, following which game engine 404 (or an instance of it) runs. At step 501, a cloud gameplay session, such as session 407, is established with user device 104, over a connection via internet 108. This may be done by any suitable means, and may be handled by platform services system 205 instead of game engine 404. Typically, a connection is established between a server and a user device using HTTP or HTTPS protocols over the internet 108.

At step 502 the user's requested game is loaded into memory 302 at games 403 if it is not already there. It may be loaded from storage 303, from another location within datacentre 101, or from a networked location. At step 503 game state 409 is established for session 407. Game state 409 includes all current settings and variables for the game, and the nature of these is dependent on the game being played. For example, the game state for a role-playing game may include the location and movement of the user's character, the location and movement of other characters and objects, the player's inventory, recent actions taken, and so on. The game state may also include the terrain and structures in the character's location. The game state may be loaded from a user's last save, or the user may be starting a fresh game with pre-determined or random variables.

Once game state 409 is established, server 201 hosts cloud gameplay session 407 by running two simultaneous threads: thread 510 sends frames to a user device, and thread 520 receives user input from the same user device. These threads run until the session is ended at step 504.

Thread 510 comprises three steps. At step 511 a frame is rendered from game state 409 and game data 406. For example, the game state may comprise the character's location, and the terrain, structures, objects and other characters at that location.

At step 512 the frame is encoded to compress it for transmission, and at step 513 it is transmitted to the user device. This is repeated many times a second to transmit a stream of frames for display on the user device.

Thread 520 comprises two steps. At step 521 user input is received from user device 104; this may for example be movement, interacting with the environment or other characters, accessing the inventory, pausing the game, and so on. At step 522 game state 409 is updated using the user input. Step 522 will be described further with reference to FIG. 8. The next frame that is rendered at step 511 will use the updated game state. Thread 520 is repeated every time user input is received.

FIG. 6 is a simplified illustrative diagram of dedicated physics simulator 204. It includes a processor 601, which may include one or more processing units such as CPUs, memory 602 such as RAM memory, and local storage 603 such as one or more disk drives. One or more network interfaces 604 provide an interface to connection 606, via which the dedicated physics simulator 204 may be configured for first use, instructions may be loaded, and requests may be served. The diagram shown in FIG. 6 is merely an example of a suitable dedicated physics simulator, and dedicated physics simulator 204 may be any kind of computer system including one or more additional graphics processing units (GPUs) or machine learning accelerators.

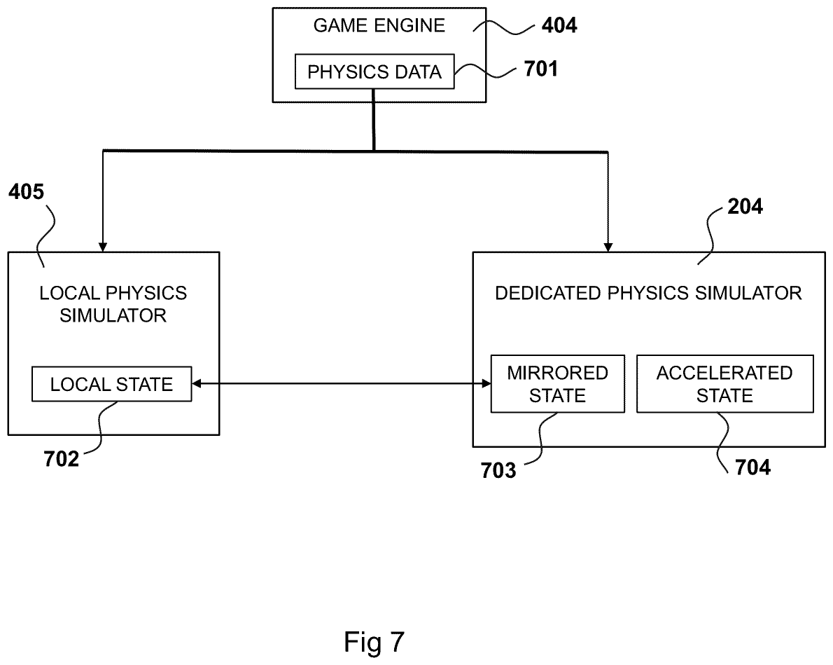

FIG. 7 is an overview of communication between game engine 404, local physics simulator 405, and dedicated physics simulator 204. The dedicated physics simulator 204 is an example of a first computing device. The cloud gaming server 201, which is an example of a second computing device, includes the local physics simulator 405.

The game engine 404 sends physics data 701, which may include object positions, orientations, velocities, collision information, and any other relevant parameters, to the dedicated physics simulator 204 and the local physics simulator 405. Depending on the requirements of the dedicated physics simulator 204 and/or local physics simulator 405, the exported physics data 701 may need to be converted into a compatible format. This could involve converting data structures, units, or coordinate systems to match those expected by the dedicated physics simulator 204 and/or local physics simulator 405.

The game engine 404 sends physics data 701 to the dedicated physics simulator 204 and the local physics simulator 405 through a defined communication protocol or interface for each of the dedicated physics simulator 204 and the local physics simulator 405. This may involve using inter-process communication (IPC) mechanisms such as sockets, shared memory, or named pipes. The physics data 701 is packaged into a message format and sent over the defined communication channel.

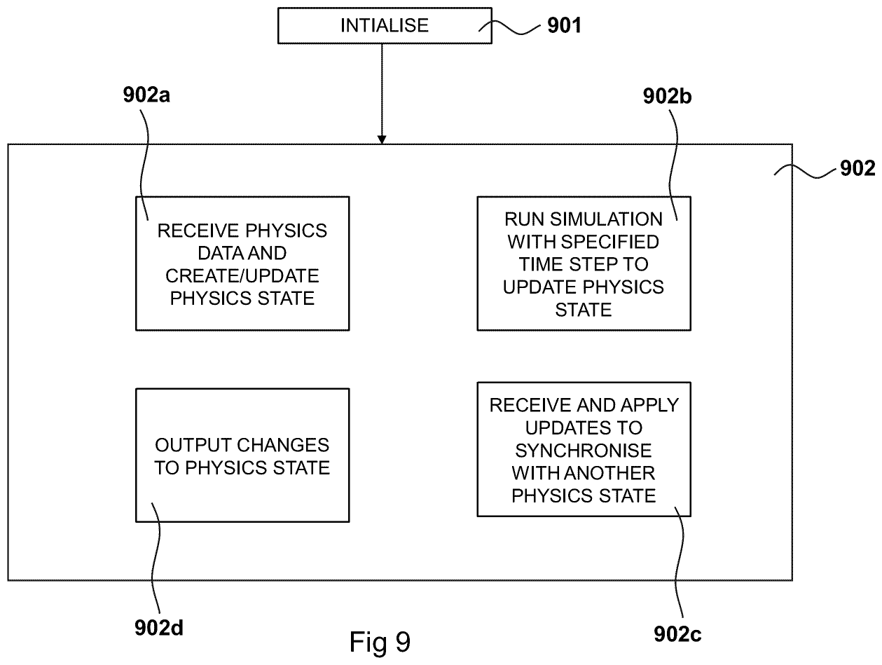

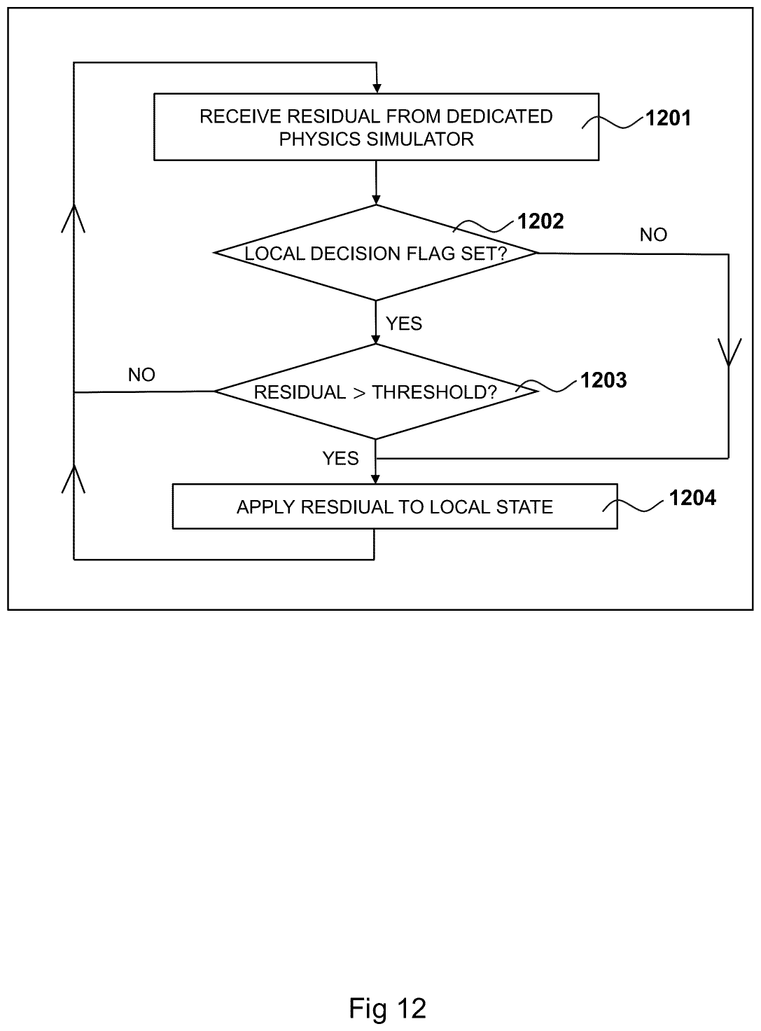

The dedicated physics simulator 204 receives the physics data 701 transmitted by the game engine 404. The dedicated physics simulator 204 runs a first simulation using the received physics data 701 to provide a mirrored state 703, which is an example of a first physics state. The mirrored state 703 is identical to local state 702, which is an example of a third physics state, and will be described further with reference to FIG. 12. The dedicated physics simulator 204 runs a second simulation using the received physics data 701 to provide an accelerated state 704, which is an example of a second physics state. The synchronisation of the dedicated physics simulator 204 and local physics simulator 405 will be described further with reference to FIGS. 9-12.

The local physics simulator 405 receives the physics data 701 transmitted by the game engine 404. The local physics simulator 405 runs a third simulation using the received physics data 701 to create/update its own local state 702. This involves integrating the received physics data 701 into the local physics simulator's 405 existing simulation loop or data structures.

FIG. 8 details step 522 (in FIG. 5) for which the game state is updated using the user input. The game engine 404 may perform the following steps in any order. At step 801, the user input is applied to the game state. Based on the input commands and the current game state, the game engine 404 provides physics data 701 (step 802). In step 803, the physics data 701 is sent to the dedicated physics simulator 204 and local physics simulator 405. In step 804, the game engine 404 receives the updated physics state from the local physics simulator 405. The updated physics state is applied to the game state, at the game engine 404, in step 805. Step 522 may not be a linear process. In particular, the physics state will be received in a constant stream, and not only in response to new physics data.

FIG. 9 shows steps to run a simulation (also referred to herein as “a third simulation”) at the local physics simulator 405. The cloud gaming server 201, which is an example of a second computing device, includes the local physics simulator 405.

At step 901, the local physics simulator 405 is initialised. Instructions for the simulation are copied to storage 303 from a networked location via the server's 201 network interfaces 304, loaded into memory 302 from storage 303 when required, and carried out by processor 301.

At step 902, the local physics simulator 405 is configured to perform a collection of threads (902a-902d). In thread 902a, the local physics simulator 405 receives physics data 701 from the game engine 404 and creates a, or updates the, physics state. Objects and their properties are updated in response to the physics data 701 to provide a physics state (local state 702).

In thread 902b, the local physics simulator 405 simulates forces i.e., simulates interactions between collision volumes and updates the physics state. For example, the received physics data 701 may comprise rigid bodies representing a character walking (e.g., collision volumes for the feet of the character), and the simulation may simulate waves on the surface of a body of water splashing against the character's feet. In the example shown in FIG. 9, the (third) simulation is run with a specified step time. The specified step time is an example of an attribute.

A flag, used to control the behaviour or flow of the simulation by indicating whether certain conditions are true or false, may be set at the local physics simulator 405 to use the dedicated physics simulator 204 if it is available. In thread 902c, the local physics simulator 405 is configured to receive and, optionally, apply updates to synchronise the local state 702 with the accelerated state 704 provided by the dedicated physics simulator 204 (described further with reference to FIG. 12).

In thread 902d, the entire physics state (e.g., the surface of the water interacting with the feet of the character) or solely changes of the entire physics state, as a result of stepping forward in time, are output to the game engine 404.

The above-described steps to run a simulation at the local physics simulator 405 continue until the local physics simulator 405 is switched off.

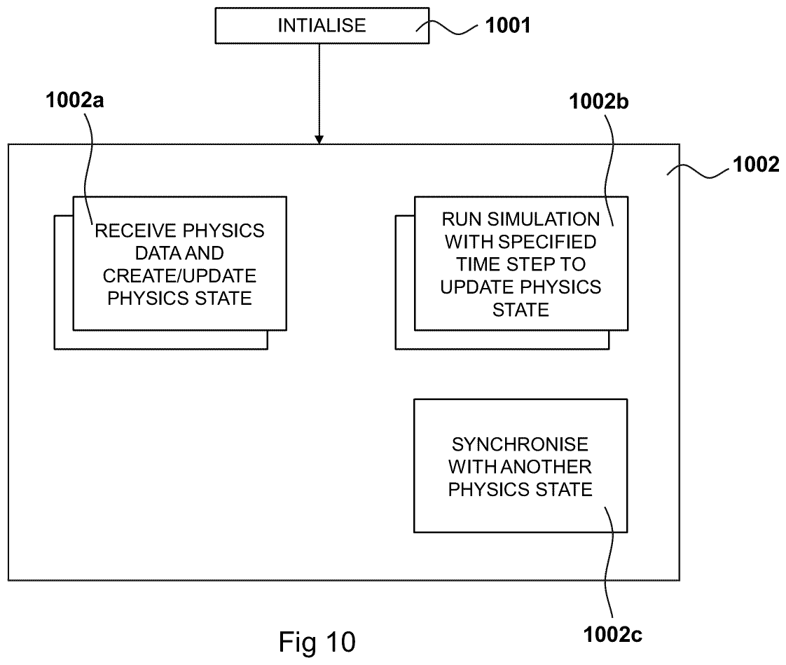

FIG. 10 shows steps to run a first simulation and second simulation at the dedicated physics simulator 204.

At step 1001, the dedicated physics simulator 204 is initialised. Instructions for the simulation are copied to storage 603 from a networked location via the dedicated physics simulator's 204 network interfaces 604, loaded into memory 602 from storage 603 when required, and carried out by processor 601.

At step 1002, the dedicated physics simulator 204 is configured to perform a collection of threads (1002a-1002c). In thread 1002a, the dedicated physics simulator 204 receives physics data 701 from the game engine 404 and creates a, or updates the, physics state. Objects and their properties/attributes are updated in response to the physics data 701 to provide a physics state.

In thread 1002b, the dedicated physics simulator 204 simulates forces i.e., simulates interactions between collision volumes and creates a, or updates the, physics state. This is done in the same way as described for the local physics simulator 405 in FIG. 9. In the example shown in FIG. 10, the first simulation is run with a specified step time, which is an example of a first attribute. The second simulation is run with a specified step time, which is an example of a second attribute. The second simulation runs at a higher rate than the first simulation.

An alternative example of another attribute may be a simulation step frequency. For example, the first simulation may run with a first simulation step frequency and the second simulation may run with a second simulation step frequency, wherein the second simulation step frequency is higher than the first simulation step frequency. The first attribute and/or second attribute may be specified by a user.

The dedicated physics simulator 204 requires more processing power than the local physics simulator 405 and produces a higher quality output (accelerated state 704), but the physics states the dedicated physics simulator 204 and the local physics simulator 405 produce are formatted the same and use the same input data (physics data 701). Thus, the attribute can be any attribute of the simulators that means one is higher quality but requires more processing that the other, and this may depend on the type of simulation being used.

Running a first simulation having a first attribute provides the mirrored state 703. Running a second simulation having a second attribute provides the accelerated state 704. Since the mirrored state 703 and the accelerated state 704 are two different physics states, these will be out of sync.

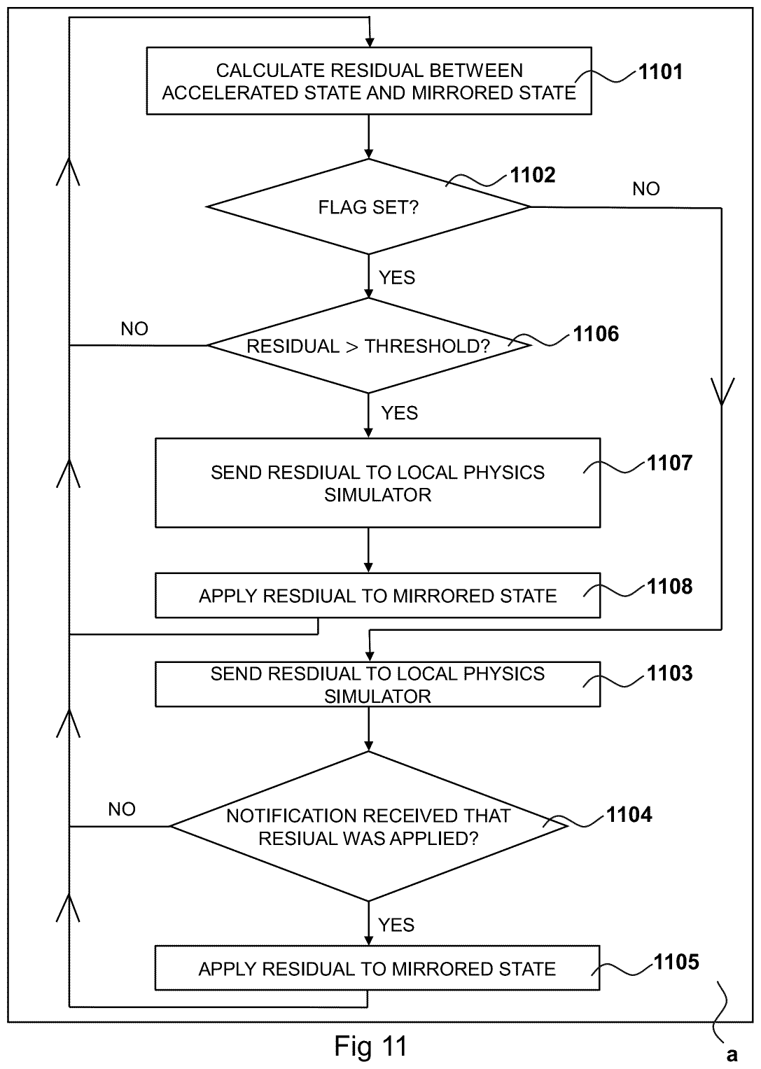

In thread 1002c, the mirrored state 703 and accelerated state 704 are synchronised (described further with reference to FIG. 11), if necessary.

FIG. 11 is an expansion of thread 1002c in FIG. 10 for synchronising the mirrored state 703 with the accelerated state 704, at the dedicated physics simulator 204. The dedicated physics simulator 204 calculates a plurality of residuals. Each residual is the difference between the accelerated state 704 and the mirrored state 703 at a selected time. The residual is the difference between the two physics states, and is a collection of values or parameters that can be applied to a physics state to make it the same as another physics state. The format of the residual is dependent upon the way in which the physics state is defined and calculated. Each residual can be considered to have a size, which is a value determined from the residual in a manner dependent upon the nature of the residual. As an example, if the physics states are defined as a collection of collision volumes, then the size of the residual could be an average difference or a maximum difference between vertices of the volumes, or between the velocities of the volumes.

In step 1101, at a selected time, the dedicated simulator 204 calculates the residual (also referred to herein as “a first residual”) between the accelerated state 704 and the mirrored state 703.

In step 1102, a determination is made as to whether a flag is set at the dedicated physics simulator 204 to determine whether to apply the calculated residual to the mirrored state 703.

If the flag is not set i.e., it is determined that the local physics simulator 405 is responsible for making the decision to apply the residual. In step 1103, the calculated residual is sent to the local physics simulator 405. In step 1104, the dedicated physics simulator 204 receives a notification, which indicates that the residual has been applied to the local state 702 at the local physics simulator 405. Once this notification is received at the dedicated physics simulator 204, the residual is applied by the dedicated physics simulator 204 to the mirrored state 703, at step 1105. Thus, the local state 702, mirrored state 703, and accelerated state 704 are synchronised.

If a notification indicating the residual has been applied to the local state 702 at the local physics simulator 405 is not received at the dedicated physics simulator 204, then the dedicated physics simulator 204 carries out step 1101 at another selected time.

If the flag is set i.e., it is determined that the dedicated physics simulator 204 is responsible for making the decision to apply the residual. Each residual has a size. The size of a residual refers to its magnitude or absolute value. For example, if the residual is the difference in velocities of a collision volume at times to (3 m/s) and t₁ (10 m/s), the size of the residual would be 7 m/s. In step 1106, the dedicated physics simulator 204 determines whether the size of the residual is larger than a threshold (also referred to herein as “a first threshold”). A threshold is a specific value or boundary that serves as a criterion for making a decision or taking action. The threshold may be set by a user or may be pre-defined in the loaded instructions. If it is determined that the size of the residual is larger than the threshold (e.g., if the residual is 7 m/s and the threshold is 5 m/s), the residual is sent to the local physics simulator 405, in step 1107. In step 1108, the residual is applied to the mirrored state 703. Thus, the local state 702, mirrored state 703, and accelerated state 704 are synchronised. If it is determined that the size of the residual is not larger than the threshold, the residual is not applied to the mirrored state 703, and the dedicated physics simulator 204 carries out step 1101 at another selected time.

FIG. 12 is an expansion of thread 902c in FIG. 9 for synchronising the local state 702 with the accelerated state 704, at the local physics simulator 405.

In step 1201, the residual is received from the dedicated physics simulator 204, at the local physics simulator 405.

In step 1202, a determination is made as to whether a flag (which is the same flag as set at the dedicated physics simulator 204) is set at the local physics simulator 405 to determine whether to apply the calculated residual to the local state 702. If the flag is not set i.e., it is determined that the dedicated physics simulator 204 is responsible for making the decision to apply the residual, then the residual is applied to the local state 702, in step 1204. Thus, the local state 702, mirrored state 703, and accelerated state 704 are synchronised.

Each residual has a size. In step 1202, if the flag is set i.e., it is determined that the local physics simulator 405 is responsible for making the decision to apply the residual, then the local physics simulator 405 determines if the received residual is greater than a threshold, in step 1203. If it is determined that the size of the residual is larger than the threshold, the residual is applied to the local state 702, in step 1204. Thus, the local state 702, mirrored state 703, and accelerated state 704 are synchronised.

If it is determined that the size of the residual is not larger than the threshold, the residual is not applied to the local state 702, and the local physics simulator 405 carries out step 1201.

Advantageously, the game always runs its physics, at the local physics simulator 405, at a low level of detail, and has the option to use high level simulation details from the dedicated physics simulator 204. Accordingly, use of the dedicated physics simulator 204 can enhance results, but the game does not rely on the dedicated physics simulator 204.

Although particular embodiments of this disclosure have been described, it will be appreciated that many modifications/additions and/or substitutions may be made within the scope of the claims.

1. A computer-implemented method, comprising the steps of, at a first computing device:
receiving physics data;
running a first simulation having a first attribute, using the physics data, to provide a first physics state;
running a second simulation having a second attribute, using the physics data, to provide a second physics state;
calculating a plurality of residuals, wherein each residual is the difference between the first physics state and the second physics state at a selected time; and
synchronising the first physics state with the second physics state by applying one of the residuals to the first physics state.

2. The computer-implemented method according to claim 1, further comprising the step of sending a first residual of the plurality of residuals to a second computing device.

3. The computer-implemented method according to claim 2, further comprising the step of, after calculating each residual:
making a determination based on the residual whether to apply the residual to the first physics state and send the residual to the second computing device.

4. The computer-implemented method according to claim 3, further comprising the steps of, at the second computing device:
receiving physics data;
running a third simulation having the first attribute, using the physics data, to provide a third physics state;
receiving the first residual from the first computing device; and
synchronising the third physics state with the second physics state by applying the first residual to the third physics state.

5. The computer-implemented method according to claim 2, further comprising the steps of, after sending the first residual to the second computing device:
receiving a notification from the second computing device; and
if the notification indicates that the second computing device has applied the first residual, determining to apply the first residual to the first physics state.

6. The computer-implemented method according to claim 5, further comprising the steps of, at the second computing device:
receiving physics data;
running a third simulation having the first attribute, using the physics data, to provide a third physics state;
receiving the first residual from the first computing device;
making a determination based on the first residual whether to apply the first residual to the third physics state, and if so:
synchronising the third physics state with the second physics state by applying the first residual to the third physics state; and
sending a notification to the first computing device that the first residual has been applied.

7. The computer-implemented method according to claim 3, wherein each residual has a size, and the step of making a determination comprises determining whether the size of the residual is larger than a first threshold.

8. The computer-implemented method according to claim 1, wherein:
the first attribute is a first simulation step frequency; and
the second attribute is a second simulation step frequency that is higher than the first simulation step frequency.

9. The computer-implemented method according to claim 8, wherein:
the first simulation step frequency and/or second simulation step frequency are/is specified by a user.

10. The computer-implemented method according to claim 3, wherein:
the physics data comprises one or more collision volumes.

11. The computer-implemented method according to claim 10, wherein:
running the first simulation, second simulation, and/or third simulation comprises simulating interactions between one or more collision volumes.

12. The computer-implemented method according to claim 11, wherein:
the first physics state, second physics state, and/or third physics state comprise(s) information on changes in a position and/or velocity of the one or more collision volumes.

13. The computer-implemented method according to claim 3, wherein:
the physics data is received from a game engine.

14. A computing device comprising a first processor, first memory and a first network interface, wherein the first processor is configured by instructions stored in the first memory to carry out the method of claim 1.

15. The system according to claim 14, wherein the computing device is a dedicated physics simulator.

16. A system comprising:
a first computing device comprising a first processor, a first memory and a first network interface; and
a second computing device comprising a second processor, a second memory and a second network interface,
wherein the first processor is configured by instructions stored in the first memory to carry out the method of:
receive physics data;
run a first simulation having a first attribute, using the physics data, to provide a first physics state;
run a second simulation having a second attribute, using the physics data, to provide a second physics state;
calculate a plurality of residuals, wherein each residual is the difference between the first physics state and the second physics state at a selected time; and
synchronize the first physics state with the second physics state by applying one of the residuals to the first physics state; and
wherein the second processor is configured by second instructions stored in the second memory to carry out the steps:
receive physics data;
run a third simulation having the first attribute, using the physics data, to provide a third physics state;
receive the first residual from the first computing device; and
synchronize the third physics state with the second physics state by applying the first residual to the third physics state.

17. The system according to claim 16, wherein the second processor is additionally configured by further instructions stored in the second memory to run a game engine, and wherein the game engine produces the physics data.

18. The system according to claim 17, wherein the second computing device is one of:
a cloud gaming server that hosts gaming sessions for one or more gaming devices;
a gaming device.

19. A computer-readable medium comprising a computer program comprising machine-readable instructions that when implemented by a computing device cause the computing device to implement a method, at a first computing device, comprising:
receiving physics data;
running a first simulation having a first attribute, using the physics data, to provide a first physics state;
running a second simulation having a second attribute, using the physics data, to provide a second physics state;
calculating a plurality of residuals, wherein each residual is the difference between the first physics state and the second physics state at a selected time; and
synchronising the first physics state with the second physics state by applying one of the residuals to the first physics state.
